(19) United States
(12) Patent Application Publication
(10) Pub. No.: US 2024/0313157 A1
(43) Pub. Date: Sep. 19, 2024

(54) LIGHT-EMITTING DIODE AND METHOD FOR MANUFACTURING THE SAME

(71) Applicant: Quanzhou Sanan Semiconductor Technology Co., Ltd., Quanzhou (CN)

(72) Inventors: Yenchin WANG, Quanzhou (CN); Jinghua CHEN, Quanzhou (CN); Huan Shao KUO, Quanzhou (CN); Yu-Ren PENG, Quanzhou (CN); Shaohua HUANG, Quanzhou (CN)

(21) Appl. No.: 18/670,189

(22) Filed: May 21, 2024

Related U.S. Application Data
(63) Continuation-in-part of application No. PCT/CN2021/132139, filed on Nov. 22, 2021.

(51) Int. Cl. H01L 33/22; H01L 33/00; H01L 33/30

(52) U.S. Cl. CPC H01L 33/22; H01L 33/0062; H01L 33/0093; H01L 33/30

(57) ABSTRACT

A light-emitting diode includes a semiconductor epitaxial structure that has a first surface and a second surface opposite to each other, and that includes a first semiconductor layer, a second semiconductor layer, an active layer, and a third semiconductor layer disposed in such order in a direction from the first surface to the second surface. The first semiconductor layer includes a first sublayer and a second sublayer. A surface of the first sublayer away from the second sublayer is the first surface. The first surface has a roughened surface. The second sublayer is closer to the second surface than the first sublayer. Each of the first sublayer and the second sublayer includes an aluminum-containing compound semiconductor material. An aluminum content of the first sublayer is smaller than that of the second sublayer. A method for manufacturing the light-emitting diode is also provided.

### CROSS-REFERENCE TO RELATED APPLICATION

This application is a continuation-in-part (CIP) of International Application No. PCT/CN2021/132139, filed on Nov. 22, 2021, the entire disclosure of which is incorporated by reference herein.

### FIELD

The disclosure relates to semiconductor technology, and more particularly to a light-emitting diode and a method for manufacturing the same.

### BACKGROUND

Light-emitting diodes (LEDs) may emit light on their own, and have

high efficiency, low power consumption, high luminous intensity, high stability, ultra-high resolution, high color saturation, fast response rate, and long life span. They are widely applied in displays, optical communications, indoor positioning, biology, and healthcare, are expected to be further used in wearable/implantable devices, augmented displays/virtual reality, in-vehicle displays, ultra-large displays, optical communication, medical detection, intelligent vehicle lights, space imaging, etc., and therefore have a bright prospect. Improving light-emitting efficiency of the LEDs is a focus of current development in the industry.

The light-emitting efficiency of the LEDs is determined by two factors: 1) the internal quantum efficiency (IQE) when electrons and holes recombine in an active layer, and 2) the light extraction efficiency. The light-emitting efficiency may be improved in various ways, including improvement on the quality of epitaxial growth, increasing chances of the electrons and the holes recombining so as to improve the internal quantum efficiency, etc. On the other hand, if light generated by a LED is unable to be extracted effectively, a portion of the light may be trapped inside the LED, reflect or refract back and forth due to total reflection, and eventually be absorbed by an electrode or the active layer of the LED, thereby being unable to increase the luminous intensity of the LED. Therefore, surface roughening or changing a geometric structure of the LED is used to improve the external quantum efficiency (EQE), and to increase the luminous intensity and the light-emitting efficiency of the LED.

Conventionally, by virtue of roughening a surface of a semiconductor epitaxial structure of the LED, the light extraction efficiency is improved, thereby improving the luminous intensity. A surface of a first semiconductor layer formed from a material represented by (AlₓGa₁₋ₓ)_{Y}I_{1-Y}P is roughened, so as to improve the light-emitting efficiency. In the material of the first semiconductor layer, X is generally no smaller than 0.5, and normally ranges from 0.5 to 0.7. When an aluminum content of the first semiconductor layer is greater, i.e., when X is greater, the material of the first semiconductor layer is more likely to be roughened by a roughening solution, so that a surface roughness (Ra) of the first semiconductor layer becomes smaller, thereby affecting the light-emitting efficiency of the LED. At the same time, the higher the aluminum content, the faster the roughening process, and the poorer the processing stability, and over-roughening may be resulted. FIG. 1 shows a conventional LED being over roughened and etched, which affects reliability of the conventional LED.

### SUMMARY

Therefore, an object of the disclosure is to provide a light-emitting diode and a method for manufacturing the same that can alleviate at least one of the drawbacks of the prior art.

According to one aspect of the disclosure, the light-emitting diode includes a semiconductor epitaxial structure that has a first surface and a second surface opposite to each other, and that includes a first semiconductor layer, a second semiconductor layer, an active layer, and a third semiconductor layer formed between the first surface and the second surface, and disposed in such order in a direction from the first surface to the second surface.

The first semiconductor layer includes a first sublayer and a second sublayer. A surface of the first sublayer away from the second sublayer is the first surface. The first surface has a roughened surface. The second sublayer is closer to the second surface than the first sublayer.

Each of the first sublayer and the second sublayer includes an aluminum-containing compound semiconductor material. An aluminum content of the first sublayer is smaller than an aluminum content of the second sublayer.

According to another aspect of the disclosure, method for manufacturing a light-emitting diode, includes steps of:

providing a growth substrate and forming a semiconductor epitaxial structure on the growth substrate, the semiconductor epitaxial structure having a first surface in contact with the growth substrate, and a second surface opposite to the first surface, and including a first semiconductor layer, a second semiconductor layer, an active layer, and a third semiconductor layer formed on the growth substrate in such order in a direction away from the growth substrate, the first semiconductor layer including a first sublayer and a second sublayer formed in such order in the direction away from the growth substrate, a surface of the first sublayer away from the second sublayer being the first surface, each of the first sublayer and the second sublayer including an aluminum-containing compound semiconductor material, an aluminum content of the first sublayer being smaller than an aluminum content of the second sublayer;

removing the growth substrate so as to expose the first surface of the first sublayer of the first semiconductor layer, and roughening the first surface of the first sublayer of the first semiconductor layer by etching, thereby forming the first surface of the first sublayer into a roughened surface.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic view of a conventional light-emitting diode being over etched during a roughening process.

FIG. 2 is a schematic view illustrating a semiconductor epitaxial structure formed on a growth substrate according to an embodiment of the disclosure.

FIG. 3 is a schematic view illustrating one of micro light-emitting diodes produced from the semiconductor epitaxial structure of FIG. 2.

FIG. 4 is a schematic view illustrating an example of one of transfer-printable light-emitting structures formed by the micro light-emitting diodes produced from the semiconductor epitaxial structure of FIG. 2.

FIG. 5 is a schematic view illustrating another example of one of transfer-printable light-emitting structures formed by the micro light-emitting diodes produced from the semiconductor epitaxial structure of FIG. 2.

FIG. 6 to FIG. 13 are schematic views illustrating a method for

manufacturing a micro light-emitting diode from the semiconductor epitaxial structure shown in FIG. 2.

FIG. 14 is a schematic view illustrating a micro light-emitting diode according to another embodiment of the disclosure.

FIG. 15 is a schematic view illustrating a micro light-emitting diode according to still another embodiment of the disclosure.

FIG. 16 is a schematic view illustrating a micro light-emitting diode according to still another embodiment of the disclosure.

FIG. 17 is a schematic view illustrating a display panel according to the disclosure.

FIG. 18 is a graph illustrating test data of a single micro light-emitting diode of FIG. 3 and one having a conventional structure.

FIG. 19 is a SEM image of a first sublayer of the micro light-emitting diode when an aluminum content is 40%.

FIG. 20 is a SEM image of the first sublayer of the micro light-emitting diode when the aluminum content is 60%.

FIG. 21 is a schematic view illustrating a micro light-emitting diode according to still another embodiment of the disclosure.

FIG. 22 is a schematic view illustrating a micro light-emitting diode according to still another embodiment of the disclosure.

FIG. 23 is a schematic view illustrating a light-emitting diode according to still another embodiment of the disclosure.

FIG. 24 is a schematic view illustrating a light-emitting diode according to still another embodiment of the disclosure.

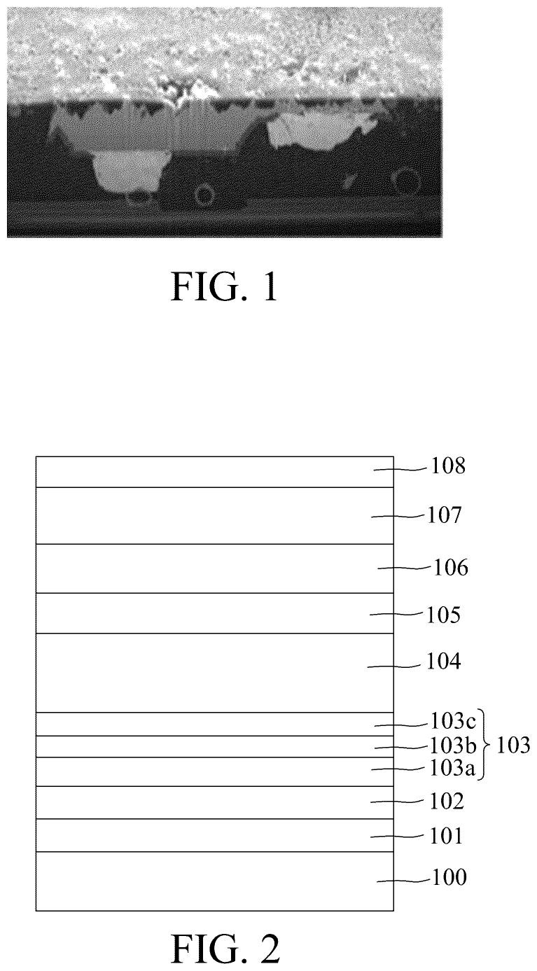

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

An embodiment of a light-emitting diode and a method for manufacturing the same are provided, which may cope with problems of easy roughening by a roughening solution and producing small surface roughness (Ra) which occur on a first semiconductor layer of a conventional light emitting diode that is formed from an aluminum-containing compound semiconductor material represented by (Al_{X}Ga_{1-X})_{Y}In_{1-Y}P and that has a high aluminum content. The small surface roughness (Ra) of the first semiconductor layer is likely to negatively affect light-emitting efficiency of the light-emitting diode. The higher the aluminum content, the faster the roughening process, and the poorer the processing stability, thereby resulting in over roughening. Therefore, by virtue of improving surface roughness of a light-exiting surface of the light-emitting diode, the light-emitting efficiency of the light-emitting diode may be improved, thereby improving reliability of the light-emitting diode.

Referring to FIG. 2, a growth substrate 100 and a semiconductor epitaxial structure before being formed into light-emitting diodes are shown. The semiconductor epitaxial structure has a first surface (S1) and a second surface (S2) that are opposite to each other, and including a first semiconductor layer 103, a second semiconductor layer, an active layer 105, and a third semiconductor layer that are formed between the first surface (S1) and the second surface (S2), and that are disposed in such order in a direction from the first surface (S1) to the second surface (S2) on the growth substrate 100. The first semiconductor layer 103 includes a first sublayer 103a, a second sublayer 103b, and a third sublayer 103c in a direction away from the growth substrate 100. Each of the first sublayer 103a, the second sublayer 103b, and the third sublayer 103c includes an aluminum-containing compound semiconductor material. An aluminum content of the first sublayer 103a is smaller than an aluminum content of the second sublayer 103b. An aluminum content of the third sublayer 103c is smaller than the aluminum content of the second sublayer 103b.

Specifically, referring to FIG. 2, the growth substrate 100 may be made of, but is not limited to, GaAs, GaP, InP, etc. In this embodiment, the growth substrate 100 is made of GaAs. In some embodiments, a buffer layer 101 and an etch top layer 102 may be disposed between the growth substrate 100 and the first semiconductor layer 103. Due to lattice quality of the buffer layer 101 being better than that of the growth substrate 100, forming the buffer layer 101 on the growth substrate 100 may alleviate adverse effects of lattice defects of the growth substrate 100 on the semiconductor epitaxial structure. The etch stop layer 102 serves to stop etching in subsequent procedures. In certain embodiments, the etch stop layer 102 is an n-type etch stop layer made of n-type gallium indium phosphide (GaInP). In other embodiments, the etch stop layer 102 is a p-type etch stop layer made of p-type gallium indium phosphide (GaInP). To facilitate a later removal of the growth substrate 100, a thickness of the etch stop layer 102 is greater than 0 nm and no greater than 500 nm. In some embodiments, the thickness of the etch stop layer 102 is greater than 0 nm and no greater than 200 nm.

Referring to FIG. 2, the first semiconductor layer 103 is disposed on the etch stop layer 102.

In some embodiments, the first sublayer 103a is formed from an aluminum-containing compound semiconductor material that is represented by (Al_{X1}Ga_{1-X1})_{Y1}In_{1-Y1}P, the second sublayer 103b is formed from an aluminum-containing compound semiconductor material that is represented by (Al_{X2}Ga_{1-X2})_{Y2}In_{1-Y2}P, and 0<X1<X2≤1. An amount of difference between X1 and X2 ranges from 0.1 to 0.35.

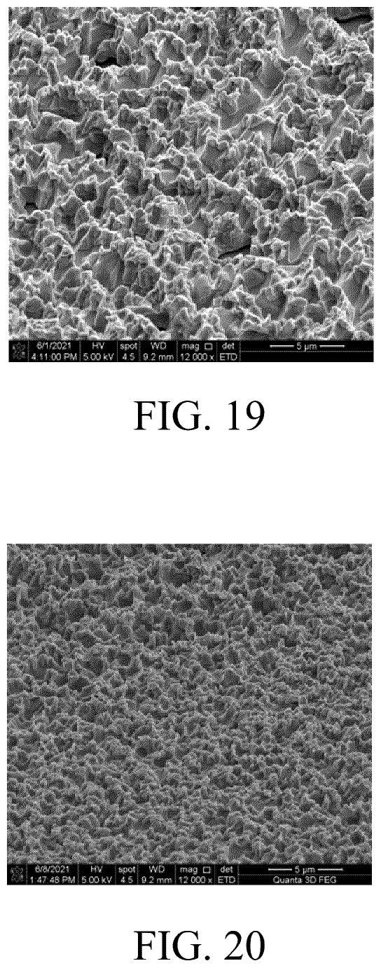

In certain embodiments, X1 of the first sublayer 103a ranges from 0.35 to 0.45, and X2 of the second sublayer 103b ranges from 0.5 to 0.7. The aluminum content of the first sublayer 103a is smaller than the aluminum content of the second sublayer 103b to ensure the first sublayer 103a to be etched at a slower rate, so that the surface roughness (Ra) of the light-exiting surface of the light-emitting diode after etching is greater, thereby improving the light-emitting efficiency of the light-emitting diode. At the same time, over etching (i.e., over roughening) of the first sublayer 103a is prevented, thereby improving reliability of the light-emitting diode. FIG. 19 is a SEM image of a roughened surface (i.e., the light-exiting surface) of the light-emitting diode when the aluminum content of the first sublayer 103a is at 40%. A surface roughness in FIG. 19 is approximately 275 nm. FIG. 20 is a SEM image of the roughened surface of the light-emitting diode when the aluminum content of the first sublayer 103a is at 60%. A surface roughness in FIG. 20 is approximately 170 nm. By comparing the data between FIG. 19 and FIG. 20, when the aluminum content of the first sublayer 103a is smaller, the surface roughness of the light-exiting surface of the light-emitting diode is greater, thereby improving the light-emitting efficiency of the light-emitting diode and increasing luminous intensity of the light-emitting diode. As a result, in this embodiment, the aluminum content of the first sublayer 103a is controlled to range from 0.35 to 0.45, so as to increase the surface roughness, thereby improving the light-emitting efficiency of the light-emitting diode.

In some embodiments, the aluminum-containing compound semiconductor material of the third sublayer 103c is represented by (Al_{X3}Ga_{1-X3})_{Y3}In_{1-Y3}P, and X3 ranges from 0.35 to 0.45.

The first semiconductor layer 103 includes the three sublayers each having a different aluminum content, so as to improve horizontal current spreading and uniformity of current spreading. By virtue of the second sublayer 103b having a greater aluminum content, light absorption of the second sublayer 103b is reduced, thereby improving the light-emitting efficiency of the light-emitting diode. By virtue of the third sublayer 103c having a smaller aluminum content than that of the second sublayer 103b, a contact resistance between a first electrode 109 (to be describe later) and the third sublayer 103c may be lowered, thereby improving the effect of ohmic contact, reducing voltage, and improving the light-emitting efficiency of the light-emitting diode.

In some embodiments, a thickness of the first sublayer 103a after epitaxial growth ranges from 1 μm to 3 μm. In other embodiments, the thickness of the first sublayer 103a after epitaxial growth is no smaller than 1.5 μm. After etching, the thickness of the first sublayer 103a is greater than 0 μm and no greater than 0.5 μm, and a thickness of the second sublayer 103b ranges from 0.5 μm to 4 μm.

In some embodiments, the thickness of the second sublayer 103b ranges from 0.8 μm to 2 μm. A certain thickness of the second sublayer 103b may improve the uniformity of current spreading. A thickness of the third sublayer 103c ranges from 1 μm to 2 μm. A thickness of the first semiconductor layer 103 is related to effectiveness of current spreading; a certain thickness of the first semiconductor layer 103 may improve the uniformity of current spreading, thereby improving photoelectric performance of the light-emitting diode. The first semiconductor layer 103 may be n-type doped or p-type doped. Doping concentrations of the first sublayer 103a, the second sublayer 103b, and the third sublayer 103c may be the same or different, and may range from 1E18/cm³ to 4E18/cm³. A doping type of the first semiconductor layer 103 is the same as a doping type of the etch stop layer 102.

The second semiconductor layer and the third semiconductor layer includes a first cladding layer 104 and a second cladding layer 106, respectively, that provide electrons or holes for the active layer 105 and that are made of a material, e.g., aluminum gallium indium phosphorus, aluminum indium phosphorus, or aluminum gallium arsenic. In some embodiments, when the active layer 105 is made of aluminum gallium indium phosphorus, aluminum indium phosphorus, or gallium indium phosphorus, the first cladding layer 104 and the second cladding layer 106 are made of aluminum indium phosphorus to provide the holes and the electrons. A doping type of the first cladding layer 104 of the second semiconductor layer is the same as that of the first semiconductor layer 103 and that of the etch top layer 102, which may be n-type or p-type. A doping type of the second cladding layer 106 of the third semiconductor layer is opposite to that of the first cladding layer 104. In some embodiments, each of the etch stop layer 102, the first semiconductor layer 103, the first cladding layer 104 is n-type doped, and the second cladding layer 106 is p-type doped, or vice versa.

In some embodiments, a thickness of the first cladding layer 104 ranges from 0.2 μm to 1.2 μm. In other embodiments, the thickness of the first cladding layer 104 ranges from 0.3 μm to 0.5 μm. By adjusting the thickness of the first cladding layer 104, internal resistance in the material of the first cladding layer 104 may be reduced, thereby lowering the voltage of the light-emitting diode and increasing the luminous intensity of the light-emitting diode. A doping concentration of the first cladding layer 104 ranges from 6E17/cm³ to 6E18/cm³. In some embodiments, a thickness of the second cladding layer 106 ranges from 0.2 μm to 1.2 μm. In some embodiments, the thickness of the second cladding layer 106 ranges from 0.4 μm to 0.6 μm. By adjusting the thickness of the second cladding layer 106, internal resistance in the material of the second cladding layer 106 may be reduced, thereby lowering the voltage of the light-emitting diode and increasing the luminous intensity of the light-emitting diode. A doping concentration of the second cladding layer 106 ranges from 7E17/cm³ to 6E18/cm³.

The active layer 105 is a light emitting area for the electrons and the holes to recombine. Depending on a wavelength of light emitted by the active layer 105, materials for the active layer 105 may vary. The active layer 105 may be a single quantum well or multiple quantum wells with a periodic structure. The active layer 105 includes a well layer and a barrier layer, and a bandgap of the barrier layer is greater than that of the well layer. By adjusting a composition of the materials of the active layer 105, when the electrons and the holes recombine, the light having a pre-determined wavelength is emitted. In this embodiment, the active layer 105 contains the materials that generate light, such as red light, yellow light, orange light, and infrared light. Specifically, the materials of the active layer 105 may generate a peak wavelength ranging from 500 nm to 950 nm, such as aluminum gallium indium phosphorus, aluminum indium phosphorus, or aluminum gallium arsenic. In this embodiments, the semiconductor epitaxial structure emits red light.

The semiconductor epitaxial structure may be formed on the growth substrate 100 by using methods such as physical vapor deposition (PVD), chemical vapor deposition (CVD), epitaxy growth technology, atomic layer deposition (ALD), etc.

To improve current spreading of the third semiconductor layer, the third semiconductor layer includes a current spreading layer 107. In some embodiments, the current spreading layer 107 is made of GaP, and has a thickness of ranging from 0.2 μm to 1.5 μm. In this embodiment, the thickness of the current spreading layer 107 ranges from 0.3 μm to 1.0 μm. By virtue of thinning the thickness of the current spreading layer 107, light absorption by the current spreading layer 107 is reduced, thereby increasing the luminous intensity of the light-emitting diode. In some embodiments, a doping concentration of the current spreading layer 107 ranges from is 9E17/cm³ to 4E18/cm³.

The third semiconductor layer further includes an ohmic contact layer 108. In some embodiments, the ohmic contact layer 108 is made of GaP, and has a thickness ranging from 0.03 μm to 0.1 μm and a doping concentration no smaller than 7E18/cm³. In some embodiments, the doping concentration of the ohmic contact layer 108 is 9E18/cm³, so as to achieve good ohmic contact.

Doping types of the current spreading layer 107, the ohmic contact layer 108, and the second cover layer 106 are the same.

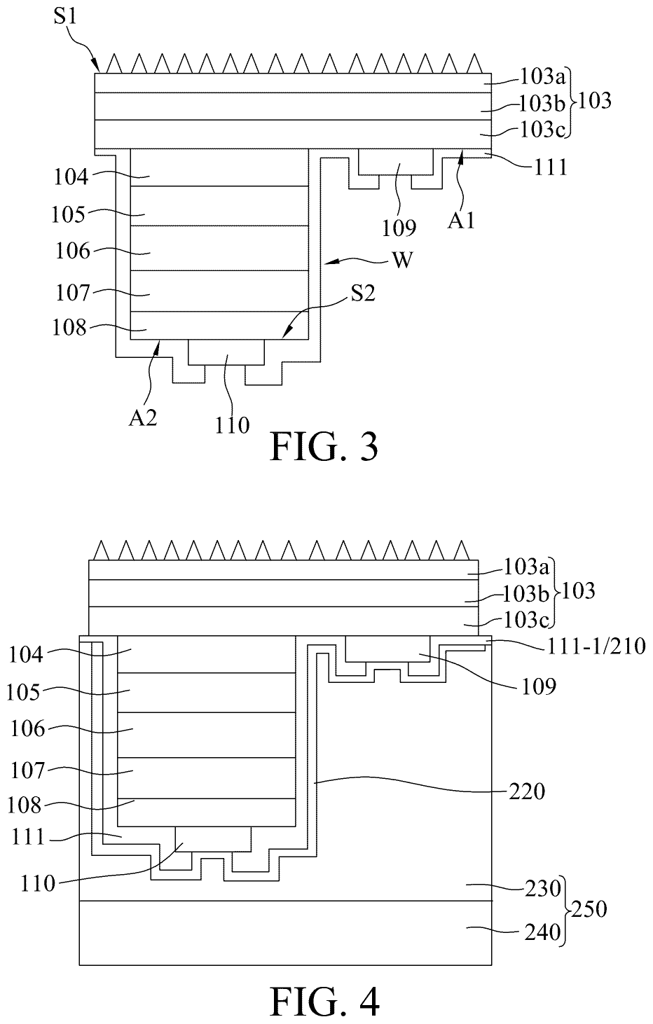

FIG. 3 is a schematic view illustrating one of micro light-emitting diodes, which are formed from the semiconductor epitaxial structure shown in FIG. 2. Due to the size of the micro light-emitting diode, a manufacturing method thereof is very different from that of a conventional light-emitting diode. In this embodiment, a dimension (i.e., length, width, or height) of the micro light-emitting diode ranges from 2 μm to 5 μm, from 5 μm to 10 μm, from 10 μm to 20 μm, from 20 μm to 50 μm, or from 50μm to 100 μm. Therefore, the micro light-emitting diode may be widely used in the display field.

Referring to FIG. 3, the micro light-emitting diode includes the

semiconductor epitaxial structure having the first surface (S1) and the second surface (S2) that are opposite to each other, and including the first semiconductor layer 103, the second semiconductor layer, the active layer 105, and the third semiconductor layer that are formed between the first surface (S1) and the second surface (S2), and that are disposed in such order in the direction from the first surface (S1) to the second surface (S2). The first semiconductor layer 103 includes the first sublayer 103a, the second sublayer 103b, and the third sublayer 103c in the direction from the first surface (S1) to the second surface (S2). A surface of the first sublayer 103a away from the second sublayer 103b is the first surface (S1), which has a roughened surface. The second sublayer 103b is closer to the second surface (S2) than the first sublayer 103a. The micro light-emitting diode further includes a first mesa surface (A1) defined by the first semiconductor layer 103 that is exposed from a recess of the semiconductor epitaxial structure, and a second mesa surface (A2) defined by the third semiconductor layer. The first electrode 109 is formed on the first mesa surface (A1), and is electrically connected to the third sublayer 103c of the first semiconductor layer 103. A second electrode 110 is formed on the second mesa surface (A2), and is electrically connected to the ohmic contact layer 108. The second semiconductor layer includes the first cladding layer 104. The third semiconductor layer includes the second cladding layer 106, the current spreading layer 107, and the ohmic contact layer 108.

The aluminum content of the first sublayer 103a is smaller than the aluminum content of the second sublayer 103b.

In some embodiments, the first sublayer 103a is formed from the aluminum-containing compound semiconductor material that is represented by (Al_{X-1}Ga_{1-X1})_{Y1}In_{1-Y}P, the second sublayer 103b is formed from the aluminum-containing compound semiconductor material that is represented by (Al_{X2}Ga_{1-X2})_{Y2}In_{1-Y2}P, and 0<X1<X2≤1. The amount of difference between X1 and X2 ranges from 0.1 to 0.35.

In some embodiments, X1 of the first sublayer 103a ranges from 0.35 to 0.45, and X2 of the second sublayer 103b ranges from 0.5 to 0.7. The aluminum content of the first sublayer 103a is smaller than the aluminum content of the second sublayer 103b to ensure the first sublayer 103a to be etched at a slower rate, so that a surface roughness (Ra) of a light-exiting surface of the micro light-emitting diode after etching is greater, thereby improving light-emitting efficiency of the micro light-emitting diode. At the same time, over etching (i.e., over roughening) of the first sublayer 103a is prevented, thereby improving reliability of the micro light-emitting diode.

The third sublayer 103c of the first semiconductor layer 103 is disposed on the second sublayer 103b of the first semiconductor layer 103. Each of the second sublayer 103b and the third sublayer 103c includes the aluminum-containing compound semiconductor material. The aluminum content of the third sublayer 103c is smaller than the aluminum content of the second sublayer 103b.

The aluminum-containing compound semiconductor material of the third sublayer 103c is represented by (Al_{X3}Ga_{1-X3})_{Y3}In_{1-Y3}P, and X3 ranges from 0.35 to 0.45.

The first semiconductor layer 103 includes the three sublayers having different aluminum contents, so as to improve horizontal current spreading and the uniformity of current spreading. By virtue of the second sublayer 103b having the greater aluminum content, light absorption of the second sublayer 103b is reduced, thereby improving the light-emitting efficiency of the micro light-emitting diode. By virtue of the third sublayer 103c having the smaller aluminum content than the second sublayer 103b, the contact resistance between the first electrode 109 and the contact electrode of the third sublayer 103c may be lowered, thereby improving ohmic contact, reducing voltage, and improving the light-emitting efficiency of the micro light-emitting diode.

To improve the light-emitting efficiency of the micro light-emitting diode, referring to FIG. 3, the surface of the first sublayer 103a away from the second sublayer 103b is the first surface (S1), which is the roughened surface and the light-exiting surface of the micro light-emitting diode. The roughened surface may have a regular or an arbitrarily irregular micro/nanostructure. The light-exiting surface that is patterned or roughened facilitates an exit of the light emitted from the active layer 105, so as to increase the light-emitting efficiency of the micro light-emitting diode. The first surface (S1) is the roughened surface that has a roughened structure with a height difference between the highest and lowest points of the roughened structure that is smaller than 1 μm, e.g., from 100 nm to 300 nm. That is to say, a surface roughness of the first surface (S1) ranges from 100 nm to 300 nm. In some embodiments, the surface roughness of the first surface (S1) ranges from 200 nm to 300 nm.

The thickness of the first sublayer 103a is greater than 0 μm and no greater than 0.5 μm. The thickness of the second sublayer 103b ranges from 0.5 um to 4 μm. In some embodiments, the thickness of the second sublayer 103b ranges from 0.8 μm to 2 μm. The thickness of the third sublayer 103c ranges from 1 μm to 2 μm. The thickness of the first semiconductor layer 103 is related to the effectiveness of current spreading; the certain thickness of the first semiconductor layer 103 may improve the uniformity of current spreading, thereby improving the light-emitting efficiency of the micro light-emitting diode.

The micro light-emitting diode further includes the first electrode 109 and the second electrode 110. The first electrode 109 is in ohmic contact with the third sublayer 103c of the first semiconductor layer 103. The first electrode 109 is made of a conductive metal, such as gold, platinum, silver, etc, or a transparent conductive oxide material, such as indium tin oxide (ITO), ZnO, etc. In some embodiments, the first electrode 109 is a multi-layered stack that at least includes an alloy material, such as a gold-germanium-nickle alloy, a gold-beryllium alloy, a gold-germanium alloy, or a gold-zinc alloy. In some embodiments, the first electrode 109 further includes a reflective metal that reflects the light emitted by the active layer 105 back to the semiconductor epitaxial structure for exiting from the light-exiting surface (i.e., the first surface (S1)).

To facilitate a good ohmic contact between the second electrode 110 and the ohmic contact layer 108 of the third semiconductor layer, each of the second electrode 110 and the ohmic contact layer 108 may be made of a conductive metal, such as gold, platinum, silver, etc. In some embodiments, the second electrode 110 is a multi-layered stack that at least includes an alloy, such as a gold-germanium-nickle alloy, a gold-beryllium alloy, a gold-germanium alloy, or a gold-zinc alloy. In some embodiments, to improve an ohmic contact between a side of the second electrode 110 and the ohmic contact layer 108, the second electrode 110 includes a diffusion metal capable of diffusing to the side of the ohmic contact layer 108 so as to improve ohmic contact resistance. To facilitate diffusion, a temperature of higher than 300° C. may be selected for melt-bonding. The diffusion metal may be gold, platinum, silver, etc., and may be in direct contact with the side of the ohmic contact layer 108.

To improve reliability of the micro light-emitting diode, an insulation layer 111 is disposed on each of the first mesa surface (A1), the second mesa surface (A2), and a mesa side wall (W) interconnecting the first mesa surface (A1) and the second mesa surface (A2). The insulation layer 111 may have a single layered structure or a multilayered structure made of at least one of SiO₂, SiNₓ, Al₂O₃, and Ti₃O₅. In some embodiments, the insulation layer 111 is a distributed Bragg reflector, e.g., the insulation layer 111 is formed by stacking Ti₃O₅ and SiO₂alternately. In this embodiment, the insulation layer 111 is made of SiNₓ or SiO₂, and has a thickness no smaller than 0.5 μm.

In this embodiment, the first electrode 109 and the second electrode 110 are disposed on a side of the semiconductor epitaxial structure opposite to the light-exiting surface (i.e., the first surface (S1)). The first electrode 109 and the second electrode 110 may be electrically connected to external components via the side of the semiconductor epitaxial structure opposite to the light-exiting surface, thereby forming a flip-chip structure. Each of the first electrode 109 and the second electrode 110 further includes a pad electrode disposed thereon. The pad electrode may include at least one layer of gold, aluminum, silver, or combinations thereof for die bonding of each of the first electrode 109 and the second electrode 110. The first electrode 109 and the second electrode 110 may or may not be equal in height. The pad electrode of the first electrode 109 and the pad electrode of the second electrode 110 do not overlap each other in a thickness direction (i.e., the direction from the first surface (S1) to the second surface (S2)).

FIG. 4 is a schematic view of an example of one of transfer-printable light-emitting structures which are formed by the light-emitting diodes produced from the epitaxial structure shown in FIG. 2 after removal of the growth substrate 100. The transfer-printable light-emitting structure includes the micro light-emitting diode, a bridging structure 210, and a base frame 250 supporting the micro light-emitting diode. The base frame 250 is disposed at a lower part of the micro light-emitting diode. The bridging structure 210 is connected to the micro light-emitting diode and the base frame 250. The base frame 250 includes a supporting substrate 240 and a bonding layer 230 disposed on the supporting substrate 240. The bonding layer 230 may be made of a benzocyclobutene (BCB) adhesive, silicone, an ultraviolet (UV) adhesive or resin. The bridging structure 210 may be made of a dielectric material, a metal material, or a semiconductor material. In certain embodiments, the bridging structure 210 is integrally formed with the insulation layer 111, and extends outwardly from the insulation layer 111. In FIG. 4, a horizontal portion 111-1 of the insulation layer 111 is the bridging structure 210. The bridging structure 210 is arranged to straddle and connect the bonding layer 230 so that the micro light-emitting diode is connected to the base frame 250.

The micro light-emitting diode is separable from the base frame 250 by transfer printing. In some cases, the transfer-printable light-emitting structure includes a sacrificial layer 220 that is disposed between the micro light-emitting diode and the base frame 250. In certain circumstances, the sacrificial layer 220 has a higher removal efficiency than that of the micro light-emitting diode and may be removed by chemical degradation or physical degradation, such as UV decomposition, etching, or pyrolysis. Examples of a material for the sacrificial layer 220 include polydimethylsiloxane (PDMS), silicone, a pyrolysis adhesive, and a UV adhesive.

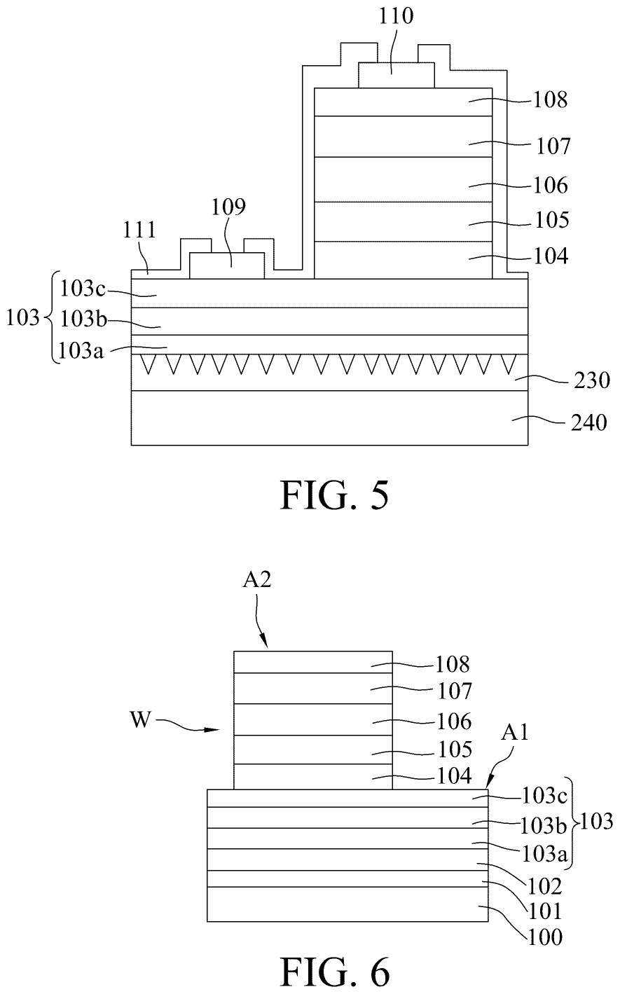

Referring to FIG. 5, compared to FIG. 4, in another example of the transfer-printable light-emitting structure, the micro light-emitting diode is bonded onto the supporting substrate 240 by the bonding layer 230. The bonding layer 230 may be made of BCB adhesive or polyimide. The supporting substrate 240 may be a sapphire substrate. In this embodiment, the micro light-emitting diode may be transferred to a packaging substrate (not shown) by laser lift-off.

FIG. 6 to FIG. 13 are schematic diagrams illustrating a method for manufacturing the micro light-emitting diode from the semiconductor epitaxial structure of FIG. 2. Detailed descriptions are given below in connection with the schematic diagrams.

First, referring to FIG. 2, the growth substrate 100 is provided, and the semiconductor epitaxial structure is formed on the growth substrate 100 by metal-organic chemical vapor deposition (MOCVD). The semiconductor epitaxial structure includes the buffer layer 101, the etch stop layer 102 adapted for removing the growth substrate 100, the first semiconductor layer 103, the first cladding layer 104, the active layer 105, the second cladding layer 106, the current spreading layer 107, and the ohmic contact layer 108 that are formed on the growth substrate 100 in such order in the direction away from the growth substrate 100. The first semiconductor layer 103 includes the first sublayer 103a, the second sublayer 103b, and the third sublayer 103c formed in such order in the direction away from the growth substrate 100. The surface of the first sublayer 103a away from the second sublayer 103b is the first surface (S1). The third sublayer 103c is disposed on the second sublayer 103b and is closer to the second surface (S2) of the semiconductor epitaxial structure than the second sublayer 103b.

Each of the first sublayer 103a and the second sublayer 103b

includes the aluminum-containing compound semiconductor material. The aluminum content of the first sublayer 103a is smaller than the aluminum content of the second sublayer 103b.

In this embodiment, the growth substrate 100 is made of GaAs, and materials of the buffer layer 101 are depended on the material of the growth substrate 100. It should be noted that, the materials of the growth substrate 100 are not limited to GaAs, and may be GaP, InP, etc., and the materials of the buffer layer 101 on the growth substrate 100 are selected correspondingly to these materials. The etch stop layer 102 is disposed on the buffer layer 101 and is made of GaInP. To facilitate a later removal of the growth substrate 100, the etch stop layer 102 has a thickness that is greater than 0 nm and no greater than 500 nm. In some embodiments, the thickness of the etch stop layer 102 is greater than 0 nm and no greater than 200 nm.

In this embodiment, each of the first sublayer 103a and the second sublayer 103b includes the aluminum-containing compound semiconductor material. The aluminum-containing compound semiconductor material of the first sublayer 103a is represented by (Al_{X1}Ga_{1-X1})_{Y1}In_{1-Y1}P, and X1 of the first sublayer 103a ranges from 0.35 to 0.45. The aluminum-containing compound semiconductor material of the second sublayer 103b is represented by (Al_{X2}Ga_{1-X2})_{Y2}In_{1-Y2}P, and X2 of the second sublayer 103b ranges from 0.5 to 0.7. The aluminum-containing compound semiconductor material of the third sublayer 103c is represented by (Al_{X3}Ga_{1-X3})_{Y3}In_{1-Y3}P, and X3 ranges from 0.35 to 0.45. As can be seen, the aluminum content of the first sublayer 103a is smaller than the aluminum content of the second sublayer 103b, and the aluminum content of the third sublayer 103c is smaller than the aluminum content of the second sublayer 103b. In this embodiment, 0<X1<X2≤1, and the amount of difference between X1 and the X2 ranges from 0.1 to 0.35.

In this embodiment, the thickness of the first sublayer 103a ranges from 1 μm to 3 μm. In some embodiments, the thickness of the first sublayer 103a is no smaller than 1.5 μm. The thickness of the first sublayer 103a may ensure a greater surface roughness in the subsequent roughening process. The thickness of the second sublayer 103b ranges from 0.8 μm to 4 μm, and the thickness of the third sublayer 103c ranges from 1 μm to 2 μm. A total thickness of the first semiconductor layer 103 is related to the effectiveness of current spreading; the certain thickness of the first semiconductor layer 103 may improve the uniformity of current spreading, thereby improving photoelectric performance of the micro light-emitting diode.

In this embodiment, the first cladding layer 104 serves to provide holes for a multi quantum well (MQW) structure, is made of AlInP, and has a thickness ranging from 0.2 μm to 1.2 μm. The first cladding layer 104 is p-type doped with magnesium (Mg), but is not limited thereto. The active layer 105 has a multi quantum well structure, which is made by repeatedly stacking well layers that are represented by Alₙ₁Ga₁₋ₙ₁InP and barrier layers that are represented by A_{In2}Ga₁₋ₙ₂InP, where 0≤n1≤n2≤1.

In some embodiments, the second cladding layer 106 is made of AlInP, and has a thickness ranging from 0.2 μm to 1.2 μm. The effectiveness of the current spreading layer 107 to spread current is related to the thickness thereof. In some embodiments, the thickness of the current spreading layer 107 ranges from 0.3 μm to 0.6 μm. In this embodiment, the thickness of the current spreading layer 107 ranges from 0.2 μm to 1.5 μm. In this embodiment, the current spreading layer 107 is made of GaP, is n-type doped, and has a doping concentration ranging from 9E17/cm³ to 4E18/cm³. In some embodiments, the ohmic contact layer 108 is made of GaP, has a thickness ranging from 0.03 μm to 0.1 μm, is n-type doped, and has a doping concentration ranging from 5E18/cm³ to 5E19/cm³. In certain embodiments, the doping concentration of the ohmic contact layer 108 is no smaller than 9E18/cm³.

Next, referring to FIG. 6, portions of the semiconductor epitaxial structure are removed by dry etching so as to form the first mesa surface (A1) and the second mesa surface (A2). The first mesa surface (A1) is defined by the first semiconductor layer 103 that is exposed from the recess of the semiconductor epitaxial structure. The second mesa surface (A2) is defined by the third semiconductor layer. The mesa side wall (W) is at a periphery of the semiconductor epitaxial structure, between the first mesa surface (A1) and the second mesa surface (A2), and interconnects the first mesa surface (A1) and the second mesa surface (A2).

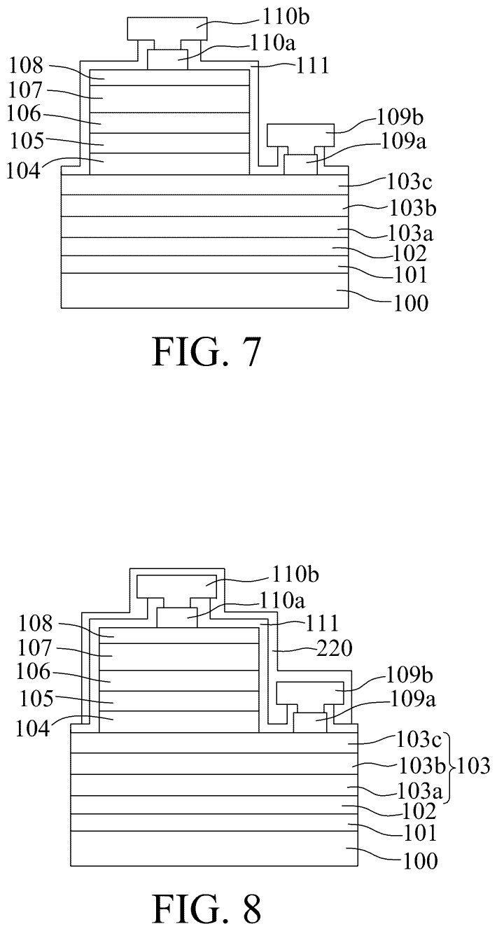

Then, referring to FIG. 7, the first electrode 109 and the second electrode 110 are disposed on the first mesa surface (A1) and the second mesa surface (A2), respectively. The first electrode 109 includes a first ohmic contact electrode 109a, and the second electrode 110 includes a second ohmic contact electrode 110a. The insulation layer 111 partially covers a top surface of each of the first ohmic contact electrode 109a and the second ohmic contact electrode 110a.

The insulation layer 111 has openings on the first ohmic contact electrode 109a and the second ohmic contact electrode 110a. A first pad electrode 109b and a second pad electrode 110b are electrically connected to the first ohmic contact electrode 109a and the second ohmic contact electrode 110a, respectively, through the openings in the insulation layer 111. Each of the first ohmic contact electrode 109a and the second ohmic contact electrode 110a may be made of Au/AuZn/Au. In this step, each of the first ohmic contact electrode 109a and the second ohmic contact electrode 110a may be fused to form a good ohmic contact with the semiconductor epitaxial structure. The insulation layer 111 may be made of SiNₓ or SiO₂, and has a thickness no smaller than 0.5 μm. In some embodiments, the insulation layer 111 is a distributed Bragg reflector, and is made by stacking alternately two different materials each having a different reflective index.

Next, referring to FIG. 8, the sacrificial layer 220 is formed on the micro light-emitting diode. In certain embodiments, the sacrificial layer 220 covering the mesa side wall (W) is no smaller than 1 μm in thickness measured from the mesa side wall (W), and is made of an oxide material, a nitride material, or a material that may be selectively removed by etching from other layers connected thereto.

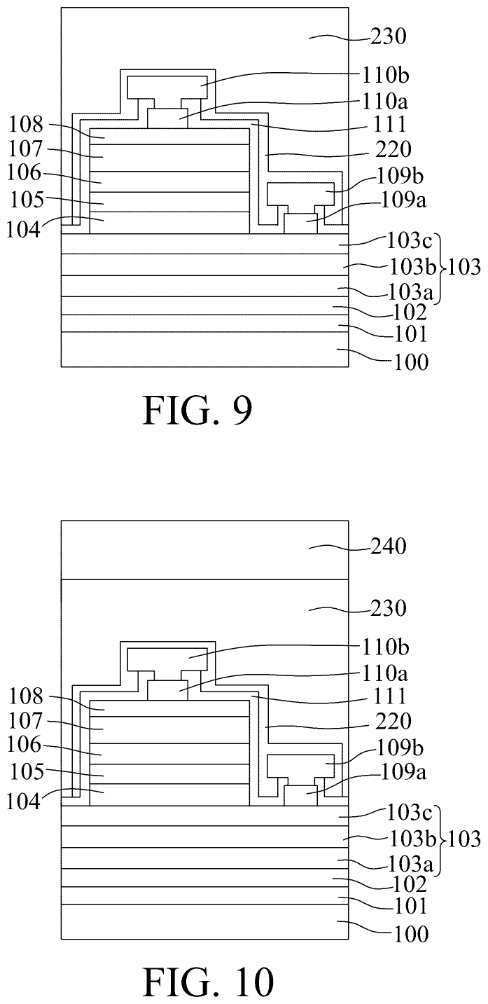

Then, referring to FIG. 9, a bonding adhesive (e.g., a BCB adhesive) is formed on the sacrificial layer 220 so as to form the bonding layer 230.

Then, referring to FIG. 10, the micro light-emitting diode along with the sacrificial layer 220 is bonded to the supporting substrate 240 by the bonding layer 230.

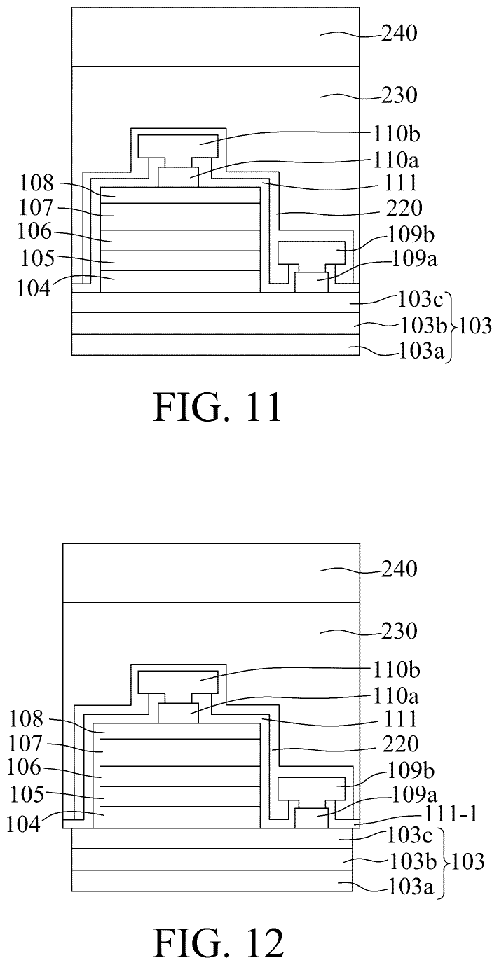

Next, referring to FIG. 11, the growth substrate 100 is removed so as to expose the first surface (S1) of the first sublayer 103a of the first semiconductor layer 103. The buffer layer 101 and the etch stop layer 102 are also removed.

Then, referring to FIG. 12, parts of the first semiconductor layer 103 at a boundary of the micro light-emitting diode are removed by masking and etching, and etching is stopped at the insulation layer 111. Individual chiplet structures which are transfer-printable are thus formed for facilitating subsequent separation of the chiplet structures.

Then, to improve the light-emitting efficiency of the micro light-emitting diode, the surface of the first sublayer 103a away from the second sublayer 103b (i.e., the first surface (S1)) is roughened by etching, thereby forming the first surface (S1) of the first sublayer 103a into the roughened structure, so as to obtain the micro light-emitting diode having the roughened surface, as shown in

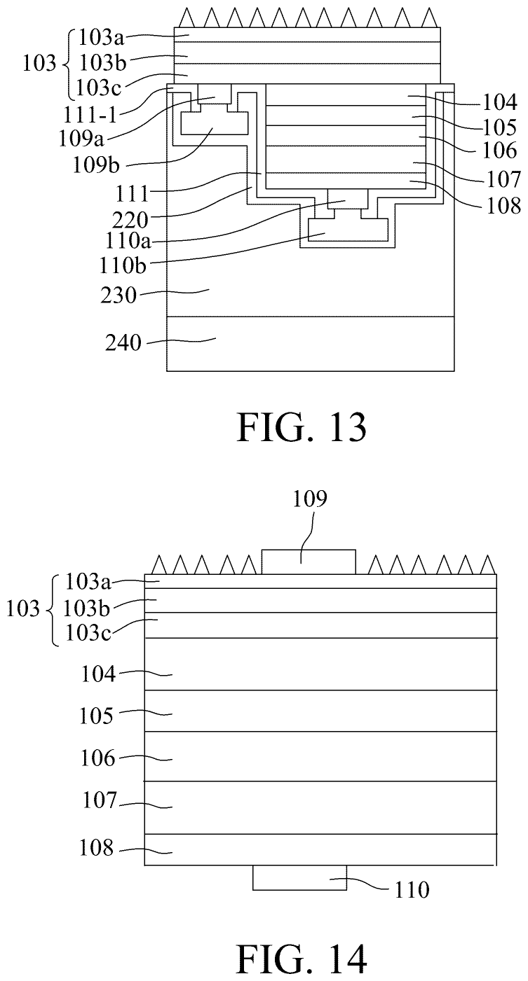

FIG. 13. In some embodiments, the surface roughness (Ra) of the first surface (S1) ranges from 100 nm to 300 nm. In other embodiments, the surface roughness (Ra) of the first surface (S1) ranges from 200 nm to 300 nm.

Finally, the micro light-emitting diode is separated from the base frame 250 by a transfer printing and is transferred onto the packaging substrate (not shown in the figure). FIGS. 3 to 13 show the light-emitting diode which has not been singulated. The light-emitting diode is singulated after it is separated from the base frame 250.

A single chip of the micro light-emitting diode having a size of 15 μm*25 μm was packaged and subjected to a luminance test. Referring to FIG. 18, under a low current of 1 μA, the luminance was 23% higher compared to that of a light-emitting diode having a conventional structure.

Referring to FIG. 14, compared to FIG. 3, in another embodiment of the micro light-emitting diode, the first electrode 109 and the second electrode 110 are disposed respectively on opposite sides of the semiconductor epitaxial structure. In this embodiment, the micro light-emitting diode has a vertical structure. The surface of the first semiconductor layer 103 away from the active layer 105 is the light-exiting surface. The ohmic contact layer 108 and the second electrode 110 may be covered by a reflective metal or a reflective insulating dielectric material (not shown), which may reflect the light emitted by the active layer 105 back to the semiconductor epitaxial structure for exiting the light from the light-exiting surface (i.e., the first surface (S1)).

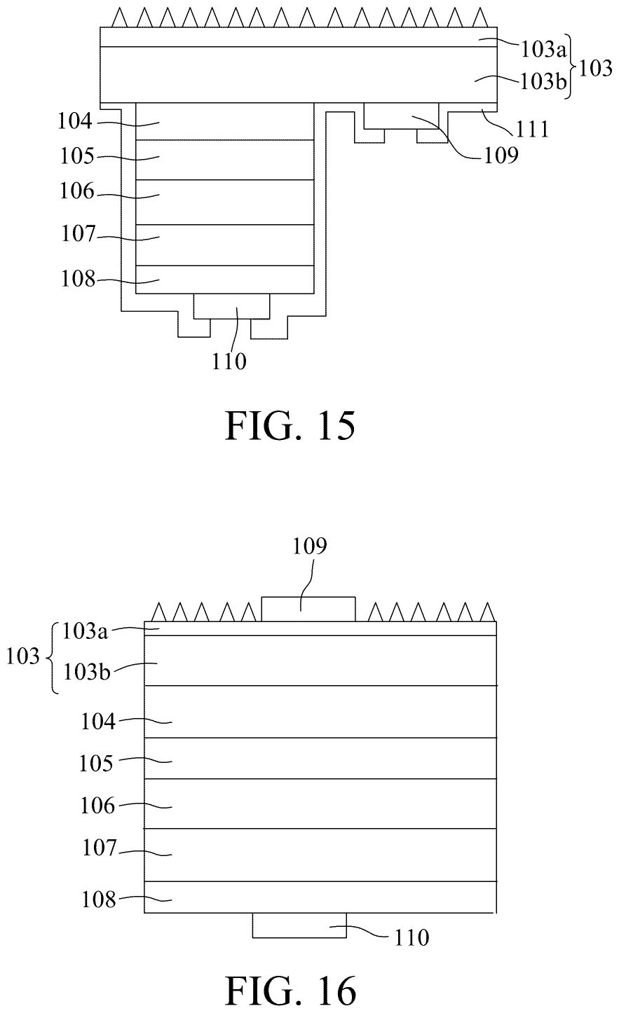

Referring to FIG. 15, compared to FIG. 3, in still another embodiment of the micro light-emitting diode, the first semiconductor layer 103 includes the first sublayer 103a and the second sublayer 103b. The surface of the first sublayer 103a away from the second sublayer 103b is the first surface (S1), which is the roughened surface. The light emitted by the active layer 105 exits from the first surface (S1). The second electrode 109 is electrically connected to the second sublayer 103b. In some embodiments, the first sublayer 103a is formed from the aluminum-containing compound semiconductor material that is represented by (Al_{X1}Ga_{1-X1})_{Y1}In_{1-Y1}P, and X1 ranges from 0.35 to 0.45. The second sublayer 103b is formed from the aluminum-containing compound semiconductor material that is represented by (Al_{X2}Ga_{1-X2})_{Y2}In_{1-Y2}P, and X2 ranges from 0.5 to 0.7.

The thickness of the first sublayer 103a is greater than 0 μm and no greater than 0.5 μm, and the thickness of the second sublayer 103b ranges from 0.8 μm to 4 μm. In some embodiments, the thickness of the second sublayer 103b is no smaller than 1.5 μm. In some embodiments, the thickness of the second sublayer 103b is no greater than 2 μm, so as to ensure the uniformity of current spreading. The aluminum content of the first sublayer 103a is smaller than the aluminum content of the second sublayer 103b to ensure the first sublayer 103a to be etched at a slower rate, so that the surface roughness (Ra) of the light-exiting surface of the micro light-emitting diode after etching is greater, thereby improving the light-emitting efficiency of the micro light-emitting diode. At the same time, over etching (i.e., over roughening) of the first sublayer 103a is prevented, thereby improving the reliability of the micro light-emitting diode.

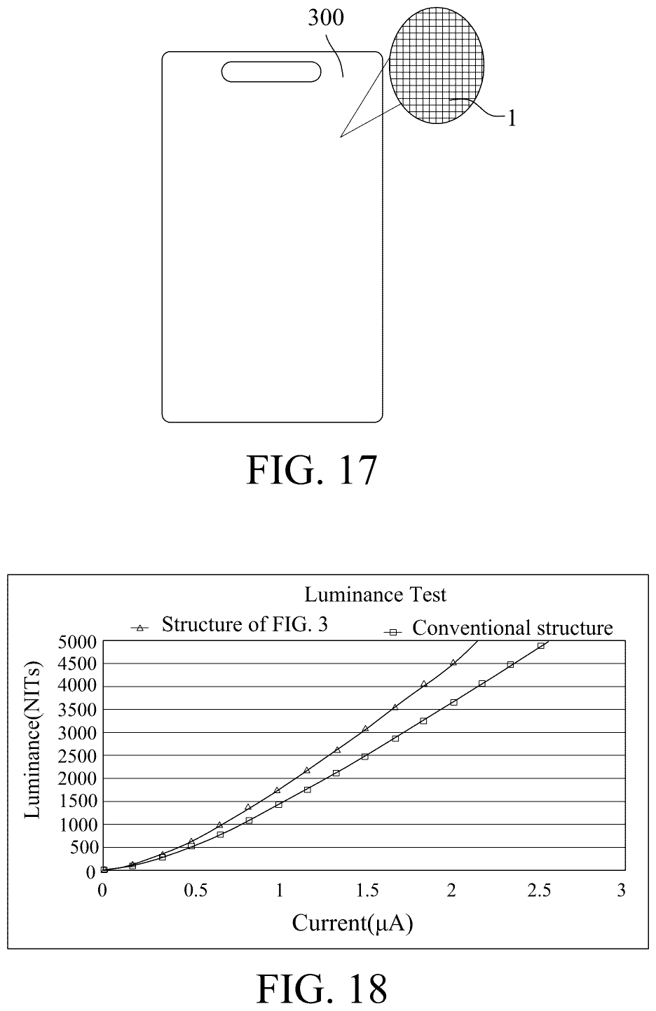

Referring to FIG. 16, compared to FIG. 3, in still another embodiment of the micro light-emitting diode, the first semiconductor layer 103 includes the first sublayer 103a and the second sublayer 103b. The surface of the first sublayer 103a away from the second sublayer 103b is the first surface (S1), which is the roughened surface. The light emitted by the active layer 105 exits from the first surface (S1). The second electrode 109 is electrically connected to the first sublayer 103a. In some embodiments, the first sublayer 103a is formed from the aluminum-containing compound semiconductor material that is represented by (Al_{X1}Ga_{1-X1})_{Y1}In_{1-Y1}P, and X1 ranges from 0.35 to 0.45. The second sublayer 103b is formed from the aluminum-containing compound semiconductor material that is represented by (Al_{X2}Ga_{1-X2})_{Y2}In_{1-Y2}P, and X2 ranges from 0.5 to 0.7. The thickness of the first sublayer 103a ranges from 0 μm to 0.5 μm, and the thickness of the second sublayer 103b ranges from 0.8 μm to 4 μm. In some embodiments, the thickness of the second sublayer 103b is no smaller than 1.5 μm. In some embodiments, the thickness of the second sublayer 103b is no greater than 2 μm, so as to ensure the uniformity of current spreading. The aluminum content of the first sublayer 103a is smaller than the aluminum content of the second sublayer 103b to ensure the first sublayer 103a to be etched at a slower rate, so that the surface roughness (Ra) of the light-exiting surface of the micro light-emitting diode after etching is greater, thereby improving the light-emitting efficiency of the micro light-emitting diode. At the same time, over etching (i.e., over roughening) of the first sublayer 103a is prevented, thereby improving the reliability of the micro light-emitting diode.

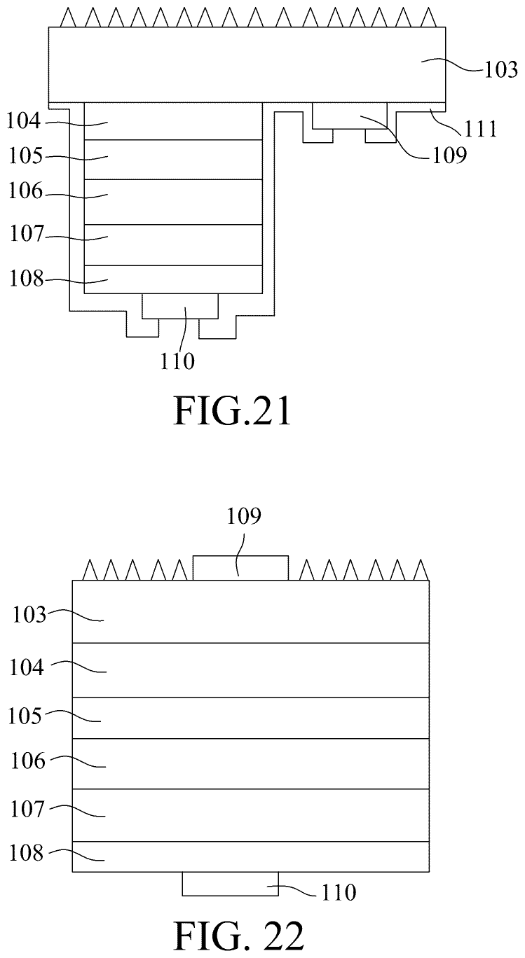

Referring to FIG. 21, compared to FIG. 3, in still another embodiment of the micro light-emitting diode, the surface of the first semiconductor layer away from the active layer 105 is the first surface (S1), which is the roughened surface. The aluminum content of the first semiconductor layer ranges from 35% to 45%, and the thickness of the first semiconductor layer ranges from 2.5 μm to 6 μm. In some embodiments, the thickness of the first semiconductor layer ranges from 2.8 μm to 4.5 μm. The thickness of the first semiconductor layer may ensure the uniformity of current spreading and enhance the photoelectric performance of the micro light-emitting diode. In this embodiment, the aluminum content of the first semiconductor layer in this embodiment ranges from 35% to 45%, so that a greater surface roughness may be obtained, thereby improving the light-emitting efficiency of the micro light-emitting diode. At the same time, over-etching is prevented, thereby improving the reliability of the micro light-emitting diode. The micro light-emitting diode shown in FIG. 21 has a flip-chip structure. The structural design of the first semiconductor layer 103 in this embodiment is also applicable to a vertical structure, as shown in FIG. 22, which may also resolve problems in the prior art and obtain the micro light-emitting diode having high light-emitting efficiency and reliability.

Referring to FIG. 17, a display panel 300 is provided and includes a plurality of the micro light-emitting diodes as described in any one of the previous embodiments. The micro light-emitting diodes are arranged in arrays. In FIG. 17, only a portion of an array of the micro light-emitting diodes is shown.

In this embodiment, the display panel 300 is a display panel of a smartphone. In other embodiments, the display panel 300 is a display panel of other electronic products, such as a display panel of a computer, or a display panel of a smart wearable device.

By virtue of the micro light-emitting diode of the aforementioned embodiments, the display panel 300 has the advantages offered by the micro light-emitting diode of the aforementioned embodiments.

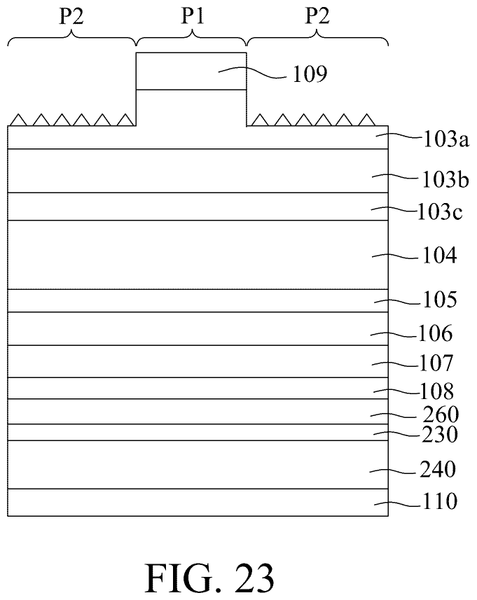

Referring to FIG. 23, the light-emitting diode is formed from the semiconductor epitaxial structure shown in FIG. 2, and is bonded onto the supporting substrate 240 by the bonding layer 230. The semiconductor epitaxial structure includes the ohmic contact layer 108, the current spreading layer 107, the second cladding layer 106, the active layer 105, the first cladding layer 104, and the first semiconductor layer 103 disposed in such order away from the supporting substrate 240. The ohmic contact layer 108, the current spreading layer 107, and the second cladding layer 106 are second type semiconductor layers. The first cladding layer 104 and the first semiconductor layer 103 are first type semiconductor layers.

In this embodiment, the supporting substrate 240 is a conductive substrate and may be made of silicon, silicon carbide or metal. Examples of the metal include copper, tungsten, molybdenum, etc. In some embodiments, the supporting substrate 240 has a thickness no smaller than 50 μm so as to have sufficient mechanical strength to support the semiconductor epitaxial structure. In addition, to facilitate further mechanical processing of the supporting substrate 240 after bonding the supporting substrate 240 to the semiconductor epitaxial structure, the supporting substrate 240 may have a thickness that is no greater than 300 μm. In this embodiment, the supporting substrate 240 is a silicon substrate.

The first semiconductor layer 103 includes the third sublayer 103c, the second sublayer 103b, and the first sublayer 103a disposed in such order away from the supporting substrate 240.

The first electrode 109 is disposed on and electrically connected to the first semiconductor layer 103.

The first semiconductor layer 103 includes two portions in a horizontal direction perpendicular to a bottom-top direction: a first portion (P1) that is located right below the first electrode 109 (i.e., the portion covered by the first electrode 109), and a second portion (P2) that is not located right below the first electrode 109 (i.e., the portion not covered by the first electrode 109). The second portion (P2) has the light-exiting surface that is not covered by and exposed from the first electrode 203. The light-exiting surface may surround the first electrode 109 and be a patterned surface or a roughened surface obtained via etching. The roughened surface may have a regular or an arbitrarily irregular micro/nanostructure. The light-exiting surface that is patterned or roughened facilitates an exit of light, so as to increase luminous efficiency of the light-emitting diode. In some embodiments, the light-exiting surface is a roughened surface that has a roughened structure a height difference between the highest and lowest points of the roughened structure that is smaller than 1 μm, e.g., from 100 nm to 300 nm.

The first semiconductor layer 103 has a contact surface that is in contact with the first electrode 109. The contact surface is not roughened because the contact surface is protected by the first electrode 109. The roughened surface of the second portion (P2) of the first semiconductor layer 103 is relatively lower than the contact surface of the first portion (P1) on a horizontal level.

The semiconductor epitaxial structure and the supporting substrate 240 may include a reflection layer 260 therebetween. The reflection layer 260 may be formed by a metal, an Omni-Directional Reflector (ODR) formed by metal and a transparent dielectric material, or a distributed Bragg reflector formed by stacking alternately two different transparent dielectric materials each having a different reflective index, such as silicon oxide and titanium oxide. The reflection layer 260 reflects the light emitted from the active layer 105 to the light-exiting surface of the first semiconductor layer 103 or a sidewall of the semiconductor epitaxial structure for the exiting of the light.

Each of the first electrode 109 and the second electrode 110 may be made of a transparent conductive material or a metal material. The transparent conductive material may be indium tin oxide (ITO) or indium zinc oxide (IZO). The metal material may be GeAuNi, AuGe, AuZn, Au, Al, Pt, and Ti, and combinations thereof.

In this embodiment, the first semiconductor layer 103 includes the three sublayers having different aluminum contents, so as to improve horizontal current spreading and the uniformity of current spreading. By virtue of the second sublayer 103b having the greater aluminum content, light absorption of the second sublayer 103b is reduced, thereby improving the light-emitting efficiency of the light-emitting diode. By virtue of the first sublayer 103a having a smaller aluminum content, the surface roughness (Ra) of the light-exiting surface of the light-emitting diode is greater, thereby improving the light-emitting efficiency of the light-emitting diode.

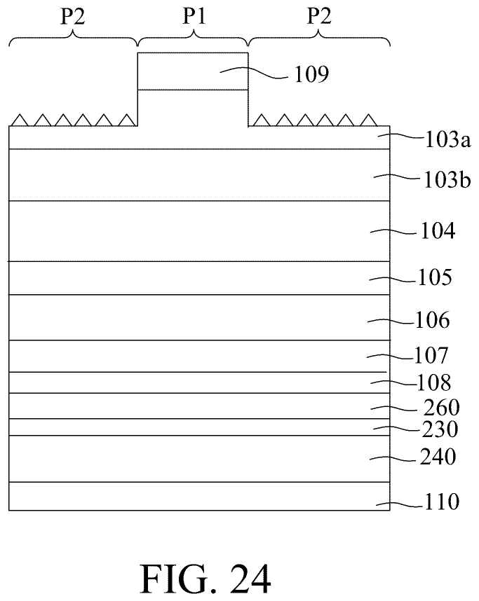

Referring to FIG. 24, compared to FIG. 23, in still another embodiment of the light-emitting diode, the first semiconductor layer 103 includes the first sublayer 103a and the second sublayer 103b. In this embodiment, the first semiconductor layer 103 includes two sublayers having different aluminum contents, so as to improve horizontal current spreading and the uniformity of current spreading. By virtue of the second sublayer 103b having the greater aluminum content, light absorption of the second sublayer 103b is reduced, thereby improving the light-emitting efficiency of the light-emitting diode. By virtue of the first sublayer 103a having a smaller aluminum content, the first sublayer 103a is etched at a slower rate, so that the surface roughness (Ra) of the light-exiting surface of the light-emitting diode after etching is greater, thereby improving the light-emitting efficiency of the light-emitting diode. At the same time, over etching (i.e., over roughening) of the first sublayer 103a is prevented, thereby improving the reliability of the light-emitting diode.

In conclusion, in this disclosure, a light-emitting diode and a method for manufacturing the same are provided, which may prevent a first semiconductor layer that is formed from an aluminum-containing compound semiconductor material represented by (Al_{X}Ga_{1-X})_{Y}In_{1-Y}P and that has a high aluminum content from being easily roughened by a roughening solution. As surface roughness (Ra) of the first semiconductor layer being smaller, light-emitting efficiency of the light-emitting diode is negatively affected. The higher the aluminum content, the faster the roughening process, and the poorer the stability of the manufacturing of the light-emitting diode as the first semiconductor layer may be over roughened. Therefore, by virtue of improving surface roughness of a light-exiting surface of the light-emitting diode, the light-emitting efficiency and luminous intensity of the light-emitting diode may be improved, thereby improving the stability of the light-emitting diode. By virtue of the first semiconductor layer being formed out of different sublayers having different aluminum contents, uniformity of current spreading is improved, thereby improving the light-emitting efficiency of the light-emitting diode.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting diode, comprising:
a semiconductor epitaxial structure having a first surface and a second surface that are opposite to each other, and including a first semiconductor layer, a second semiconductor layer, an active layer, and a third semiconductor layer that are formed between the first surface and the second surface, and that are disposed in such order in a direction from the first surface to the second surface;
wherein said first semiconductor layer includes a first sublayer and a second sublayer, a surface of said first sublayer away from said second sublayer being said first surface, said first surface having a roughened surface, said second sublayer being closer to said second surface than said first sublayer;
wherein each of said first sublayer and said second sublayer includes an aluminum-containing compound semiconductor material, an aluminum content of said first sublayer being smaller than an aluminum content of said second sublayer.

2. The light-emitting diode as claimed in claim 1, wherein said first sublayer is formed from an aluminum-containing compound semiconductor material that is represented by (Al_{X1}Ga_{1-X1})_{Y1}In_{1-Y1}P, and said second sublayer is formed from an aluminum-containing compound semiconductor material that is represented by (Al_{X2}Ga_{1-X2})_{Y2}In_{1-Y2}P, 0<X1<X2≤1, an amount of difference between X1 and X2 ranging from 0.1 to 0.35.

3. The light-emitting diode as claimed in claim 2, wherein X1 of said first sublayer ranges from 0.35 to 0.45, and X2 of said second sublayer ranges from 0.5 to 0.7.

4. The light-emitting diode as claimed in claim 1, wherein a thickness of said first sublayer is greater than 0 μm and no greater than 0.5 μm , and a thickness of said second sublayer ranges from 0.8 μm to 4 μm

5. The light-emitting diode as claimed in claim 1, wherein a surface roughness of said first surface ranges from 100 nm to 300 nm.

6. The light-emitting diode as claimed in claim 5, wherein said surface roughness of said first surface ranges from 200 nm to 300 nm.

7. The light-emitting diode as claimed in claim 1, wherein said first semiconductor layer further includes a third sublayer that is disposed on said second sublayer and that is closer to said second surface than said second sublayer.

8. The light-emitting diode as claimed in claim 7, wherein said third sublayer includes an aluminum-containing compound semiconductor material, an aluminum content of said third sublayer being smaller than said aluminum content of said second sublayer.

9. The light-emitting diode as claimed in claim 8, wherein said aluminum-containing compound semiconductor material of said third sublayer is represented by (Al_{X3}Ga₁₋ₓ₃)_{Y3}In_{1-Y3}P, X3 ranging from 0.35 to 0.45.

10. The light-emitting diode as claimed in claim 7, wherein a thickness of said third sublayer ranges from 1 μm to 2 μm, and a thickness of said second sublayer ranges from 0.8 μm to 2 μm.

11. The light-emitting diode as claimed in claim 1, wherein a dimension of said light-emitting diode ranges from 2 μm to 5 μm, from 5 μm to 10 μm, from 10 μm to 20 μm from 20 μm to 50 μm or from 50 μm to 100 μm.

12. A method for manufacturing a light-emitting diode, comprising steps of:
providing a growth substrate and forming a semiconductor epitaxial structure on the growth substrate, the semiconductor epitaxial structure having a first surface in contact with the growth substrate, and a second surface opposite to the first surface, and including a first semiconductor layer, a second semiconductor layer, an active layer, and a third semiconductor layer formed on the growth substrate in such order in a direction away from the growth substrate, the first semiconductor layer including a first sublayer and a second sublayer formed in such order in the direction away from the growth substrate, a surface of the first sublayer away from the second sublayer being the first surface, each of the first sublayer and the second sublayer including an aluminum-containing compound semiconductor material, an aluminum content of the first sublayer being smaller than an aluminum content of the second sublayer;
removing the growth substrate so as to expose the first surface of the first sublayer of the first semiconductor layer, and roughening the first surface of the first sublayer of the first semiconductor layer by etching, thereby forming the first surface of the first sublayer into a roughened surface.

13. The method as claimed in claim 12, wherein a surface roughness of the first surface ranges from 100 nm to 300 nm.

14. The method as claimed in claim 13, wherein the surface roughness of the first surface ranges from 200 nm to 300 nm.

15. The method as claimed in claim 12, wherein the aluminum-containing compound semiconductor material of the first sublayer is represented by (Al_{X1}Ga_{1-X1})_{Y1}In_{1-Y1}P, and the aluminum-containing compound semiconductor material of the second sublayer is represented by (Al_{X2}Ga_{1-X2})_{Y2}In_{1-Y2}P, 0<X1<X2≤1, an amount of difference between X1 and the X2 ranging from 0.1 to 0.35.

16. The method as claimed in claim 15, wherein X1 of the first sublayer ranges from 0.35 to 0.45, and X2 of the second sublayer ranges from 0.5 to 0.7.

17. The method as claimed in claim 12, wherein the first semiconductor layer further includes a third sublayer that is disposed on the second sublayer and that is closer to the second surface of the semiconductor epitaxial structure than the second sublayer.

18. The method as claimed in claim 17, wherein the third sublayer includes an aluminum-containing compound semiconductor material, an aluminum content of the third sublayer being smaller than the aluminum content of said second sublayer.

19. The method as claimed in claim 18, wherein the aluminum-containing compound semiconductor material of the third sublayer is represented by (Al_{X3}Ga_{1-X3})_{Y3}In_{1-Y3}P, X3 ranging from 0.35 to 0.45.

20. A display panel, comprising the light-emitting device as claimed in claim 1.
